(19) United States
(12) Patent Application Publication
(10) Pub. No.: US 2025/0324547 A1
(43) Pub. Date: Oct. 16, 2025

(54) FLEXIBLE HEAT EXCHANGE DEVICE

(71) Applicant: Raytheon Company, Arlington, VA (US)

(72) Inventors: Kimberly R. Saviers, Glastonbury, CT (US); Miad Yazdani, South Windsor, CT (US); Jason G. Milne, El Segundo, CA (US); James S. Wilson, Hurst, TX (US); Andrzej E. Kuczek, Bristol, CT (US)

(21) Appl. No.: 19/175,060

(22) Filed: Apr. 10, 2025

Related U.S. Application Data
(60) Provisional application No. 63/632,507, filed on Apr. 10, 2024.

(51) Int. Cl. H05K 7/20

(52) U.S. Cl. CPC H05K 7/20336; H05K 7/20309; H05K 7/20318

(57) ABSTRACT

A heat exchange device for an electromechanical system. The heat exchange device can include an evaporator, a condenser, and a flexible heat flow element (or “ribbon” section) that connects the evaporator and the condenser. The “ribbon” section can receive heat, from heat source associated with the electromechanical system, via the evaporator. The condenser can be coupled to a structural element that is part of a movable component of the electromechanical system. The condenser receives heat from the evaporator via the “ribbon” section. The condenser interfaces with an enclosure of the electromechanical system to provide both a thermal connection between the condenser element and the enclosure and a structural connection between the movable component and the enclosure, via the structural element.

### CROSS-REFERENCE TO RELATED APPLICATIONS

This application claims the benefit of priority to U.S. Application No. 63/632,507 filed Apr. 10, 2024, the disclosure of which is incorporated herein by reference in its entirety.

### BACKGROUND

Modern electronic systems, such as servers, avionics, and vehicle systems often generate a large amount of heat from processors and other components. This heat can degrade the performance of the system and may even damage the system over time. Many systems therefore include technology to dissipate heat and protect the system. For example, some air-cooling solutions include one or more fans. This solution is relatively low cost but has several disadvantages, including limiting the packaging density of the electronic systems because of space needed for air flow, lower efficiency (lower amount of heat transferred), and reliability of the fans. Liquid-cooling (e.g., with cold plates) can have higher cooling efficiency, but typically requires a pumped liquid loop, including numerous fluid connections, which can pose a risk of leaking and pump failure. This technique also takes up space, which can limit the density of the system.

### SUMMARY

An initial overview of the inventive concepts is provided below and then specific examples are described in further detail later. This initial summary is intended to aid readers in understanding the examples of the present technology more quickly, but is not intended to identify key features or essential features of the examples, nor is it intended to limit the scope of the present technology or the claimed subject matter.

In one example, the present technology sets forth a heat exchange device for an electromechanical system. The heat exchange device can include an evaporator, a condenser, and a flexible heat flow element (also referred to as an “adiabatic” section or a “ribbon” section) that connects the evaporator and the condenser. The “ribbon” section can receive heat, from heat source associated with the electromechanical system, via the evaporator. The condenser can be coupled to a structural element that is part of a movable component of the electromechanical system. The condenser receives heat from the evaporator via the ribbon or adiabatic section. The condenser interfaces with an enclosure of the electromechanical system to provide both a thermal connection between the condenser element and the enclosure and a structural connection between the movable component and the enclosure.

In some examples, the heat exchange device may include a set of closed loop fluid channels containing a mixture of liquid slugs and vapor bubbles, which transfers heat from the evaporator, through the flexible ribbon section (e.g., an adiabatic middle section), to the condenser, where heat is rejected. The heat can be rejected to the enclosure or to a heat sink included, or in thermal communication with, the enclosure. For example, the evaporator can be attached to a heat source associated with the electromechanical system, such as a processor, a radio-frequency (RF) transceiver, or a power-management circuit and the “ribbon” (e.g., the flexible heat flow element) can receive heat from the heat source (via the evaporator). The condenser can be coupled to (or integrated with) the structural element, such as a server rail or a structural surface of an avionics system (or “avionics enclosure”). The condenser receives heat from the evaporator (via the “ribbon”). The structural element, when engaged with an enclosure of the electromechanical system can thus provide both a thermal connection between the condenser element and the enclosure (via the structural element) and the structural connection between the movable component and the enclosure.

In another example, the present technology sets forth a structural component for a mechanical connection to an electromechanical system. The structural component includes a rigid body that can connect to a movable component of the electromechanical system to provide the mechanical connection between the movable component and an enclosure of the electromechanical system. The structural component also includes a condenser element, which can be integrated with the rigid body. The condenser element can couple to an evaporator element via a flexible heat flow element (or “ribbon” section) to enable heat to flow from the evaporator element to the condenser element through the flexible heat flow element. The condenser element can also provide a thermal connection to the enclosure (e.g., between the condenser element and the enclosure).

In some examples, the structural component can be a server rail or a structural surface of an avionics system. The thermal connection between the condenser element and the enclosure allows heat to be rejected to the enclosure or to a heat sink that is included, or in thermal communication, with the enclosure. The structural component, when engaged with an enclosure of the electromechanical system can thus provide both the thermal connection between the condenser element and the enclosure and the mechanical connection between the movable component and the enclosure.

In still another example, the present technology sets forth a method for configuring an electromechanical assembly that includes at least one movable element. The method includes coupling at least one condenser element with a structural member of the movable component of the electromechanical assembly and facilitating a thermal connection between the at least one condenser element and at least one evaporator element via at least one flexible heat flow element (or “ribbon” section). The at least one evaporator element enables thermal connectivity with a heat source. The method also includes providing a structural connection between the movable component and an enclosure of the electromechanical assembly using the structural member coupled with the condenser element and also providing a thermal connection between the condenser element and the enclosure of the electromechanical assembly using the condenser element coupled with the structural member. The method also includes facilitating conveyance of heat from the at least one evaporator element to the enclosure of the electromechanical assembly via the condenser element coupled with the structural member.

In some examples, the electromechanical system or assembly can be a server cabinet or an avionics system. The structural member can be a server rail or a structural surface of an avionics system. The thermal connection between the condenser element and the enclosure allows heat to be rejected to the enclosure or to a heat sink that is included, or in thermal communication, with the enclosure. The structural member, when engaged with an enclosure of the electromechanical assembly can thus provide both the thermal connection between the condenser element and the enclosure and the mechanical connection between the movable component and the enclosure.

### BRIEF DESCRIPTION OF THE DRAWINGS

Features and advantages of the invention will be apparent from the detailed description which follows, taken in conjunction with the accompanying drawings, which together illustrate, by way of example, features of the invention; and, wherein:

FIG. 1A illustrates an example heat exchange device for an electromechanical system that can be used to implement a flexible heat exchange device that includes evaporator elements, condenser elements, and a flexible heat flow element;

FIG. 1B illustrates various example configurations of the flexible heat exchange device that includes additional evaporator elements and condenser elements;

FIG. 1C illustrates example structural connections between a structural element of a movable component of the electromechanical system and a mating interface of an enclosure of the electromechanical system;

FIG. 2 illustrates an example structural component for a mechanical connection to an electromechanical system that can be used to implement a flexible heat exchange device; and

FIG. 3 is a flow diagram that illustrates an example method 300 for configuring an electromechanical assembly that includes at least one movable component.

Reference will now be made to the examples illustrated, and specific language will be used herein to describe the same. It will nevertheless be understood that no limitation of scope is thereby intended.

### DETAILED DESCRIPTION

The following detailed description of exemplary embodiments of the present technology refers to the accompanying drawings, which form a part hereof and in which are shown, by way of illustration, examples in which the present technology may be practiced. While these exemplary embodiments are described in sufficient detail to enable those skilled in the art to practice the present technology, it should be understood that other embodiments may be realized and that various changes to the present technology may be made without departing from the spirit and scope of the present technology. Thus, the following more detailed description of the embodiments of the present technology is not intended to limit the scope of the invention, as claimed, but is presented for purposes of illustration only to describe the features and characteristics of the present technology, and to sufficiently enable one skilled in the art to practice the invention.

### Description of Terms

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, “adjacent” refers to the proximity of two structures or elements. Particularly, elements that are identified as being “adjacent” may be either abutting or connected. Such elements may also be near or close to each other without necessarily contacting each other. The exact degree of proximity may in some cases depend on the specific context.

As used herein, the terms “electromechanical system” or “electromechanical assembly” is a top-level description of an assembly or system that includes or is associated with a heat source and may implement the flexible heat exchange device to cool the heat source. For example, a server cabinet or an avionics system and enclosure.

As used herein, the term “elastically bendable” refers to a property of a material in which the material changes shape (e.g., bends) when a force is applied and returns to its original shape when the force is removed. For example, when a force is applied to a rubber band, it stretches. When the force is removed, it goes back to its original shape.

As used herein, the term “plastically bendable” refers to a property of a material in which the material changes shape (e.g. bends) when a force is applied and does not return to its original shape when the force is removed. Rather, another force must be applied to change its shape again. For example, when a force is applied to a paperclip, it changes shape and holds the new shape until another force is applied).

### Examples of the Technology

To further describe the present technology, example embodiments are now set forth and described with reference to the figures. These example embodiments are not intended to be limiting in any way.

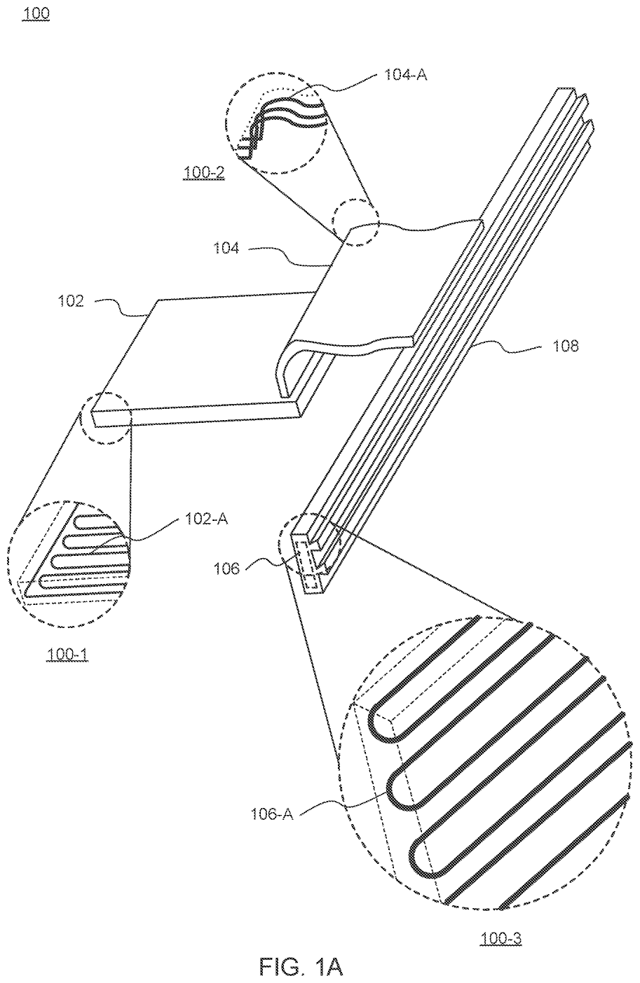

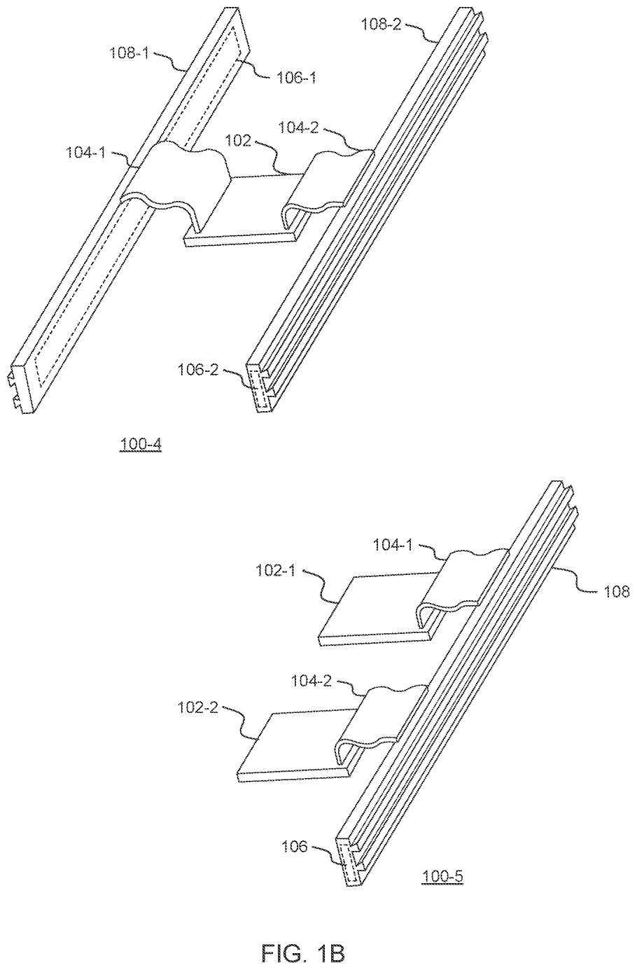

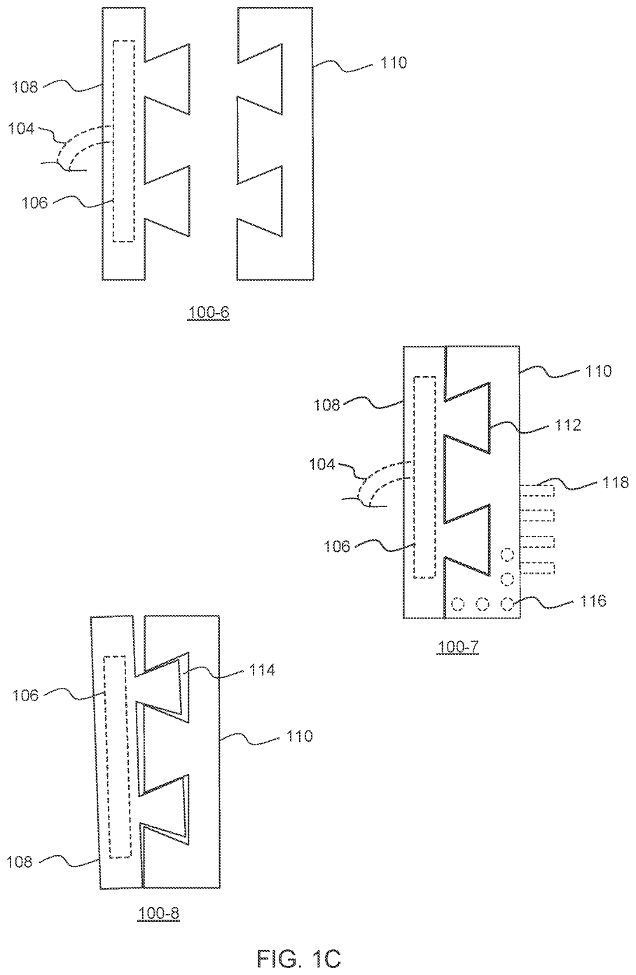

FIG. 1A illustrates an example heat exchange device 100 for an electromechanical system that can be used to implement a flexible heat exchange device. As illustrated, the example heat exchange device 100 includes an evaporator element 102, a flexible heat flow element 104, a condenser element 106, and a structural element 108. In some implementations, the example heat exchange device 100 can be an oscillating (or pulsating) heat pipe (OHP). In some further implementations, the heat exchange device 100 can be a standard heat pipe (constant or variable conductance) or a vapor chamber. An OHP can be fabricated as a two-phase passive heat exchanger made from a closed-loop network of fluid channels running between a heat-receiving section (e.g., the evaporator element 102) and a heat-rejecting section (e.g., the condenser element 106). The OHP is placed under vacuum and a filled partially with a working fluid. The working fluid distributes itself as a mixture of liquid slugs and vapor bubbles (or plugs) inside the channels. Heat “flows” from the evaporator element 102 to the condenser element 106 by an oscillating action (e.g., pulsation) of the slug-bubble system. These pressure oscillations are thermally driven and therefore no external power is required for the heat/fluid flow.

The evaporator element 102 can be constructed to be coupled to a heat source associated with the electromechanical system, such as a processor, an RF transceiver, or a power-management component. The evaporator element 102 makes a thermal connection (e.g., a low-thermal-resistance connection) with the heat source to transfer heat away from the heat source. As noted above, the heat exchange device can be made from a closed-loop network of fluid channels running between the evaporator element 102 and the condenser element 106, through the flexible heat flow element 104. In FIG. 1A, the evaporator element 102 is shown as a rigid body with the evaporation portion of the internal channels shown in a detail view 100-1 as evaporator channels 102-A.

The flexible heat flow element 104 is a flexible “′ribbon” that is coupled to the evaporator element 102 to receive heat from the heat source (e.g., via the evaporator element 102). The flexible heat flow element 104 (sometimes referred to as the adiabatic section of the OHP) is in fluid and thermal communication with the condenser element 106, for example via channels in the flexible heat flow element 104. The flexible heat flow element 104 can be made from any of a variety of ductile, non-brittle, bendable materials (e.g., metals, polymers). In some cases, the heat flow element 104 is elastically bendable, in others, plastically bendable.

The flexible heat flow element 104 can be made from a single part with the channels etched or cut through or as multiple parts with a channel etched or cut into one or both parts, which are then fused together. In some implementations, the channels can include a separate part (e.g., flexible metal or foil tubing) that is inserted in the channels. In other implementations, the flexible heat flow element can be made entirely of the flexible tubing or other components that allow the working fluid to be distributed between the evaporator element 102 and the condenser element 106. The flexible heat flow element 104 can be bent in different orientations to fit the configuration of the electronics package of the electromechanical system. As shown in FIG. 1A, flexible heat flow element 104 is shown as a formed rigid body with the flexible portion of the internal channels shown in a detail view 100-2 as flexible channels 104-A.

The condenser element 106 is constructed to be connected to the flexible heat flow element 104 and couple to a structural element 108 of a movable component of the electromechanical system. The coupling to the structural element 108 can be a removable connection or non-removable (e.g., the condenser element 106 can be integrated with the structural element 108). The condenser element 106 can then receive heat from the evaporator element 102 via the flexible heat flow element 104. In FIG. 1A, the condenser element 106 is shown as included within the structural element 108, with the condensation portion of the internal channels shown in a detail view 100-3 as condenser channels 106-A.

In some implementations, the heat exchange device 100 can include one or more additional evaporator element 102 and/or one or more additional condenser element 106. In such an implementation, the flexible heat flow element 104 can be divided to connect multiple evaporator elements 102 to one condenser element 106, multiple condenser elements 106 to one evaporator element 102, or multiple condenser elements 106 to multiple evaporator elements 102. In this way, the heat exchange device 100 can be used with electromechanical systems that include or are associated with multiple heat sources and/or heat sinks and on non-planar surfaces, or be routed around dividers and through openings as required by the overall configuration of the electromechanical system.

Consider FIG. 1B, which illustrates example configurations of a flexible heat exchange device with additional evaporator elements 102 and condenser elements 106. The examples show the structural elements 108-1 and 108-2 as rails (e.g., for a server rack), but other configurations are possible. A detail view 100-4 shows an example with two condenser elements 106-1 and 106-2 and one evaporator element 102. The detail view 100-4 shows perspective views of the structural elements 108-1 and 108-2, including condenser elements 106-1 and 106-2, respectively. The condenser elements 106-1 and 106-2 are connected to the evaporator element 102 via flexible heat flow elements 104-1 and 104-2, respectively. This configuration can allow the heat exchange device (e.g., the example heat exchange device 100) to handle components that produce more heat because there are two condenser elements.

Another detail view 100-5 shows an example with two evaporator elements 102-1 and 102-2 and one condenser element 106. The detail view 100-5 shows perspective views of the structural element 108, including the condenser element 106. The evaporator elements 102-1 and 102-2 are connected to the condenser element 106 via flexible heat flow elements 104-1 and 104-2, respectively. This configuration can allow the heat exchange device (e.g., the example heat exchange device 100) to handle multiple heat sources on the movable component with only one condenser.

Returning now to FIG. 1A: The structural element 108 can include or be a part of a rigid body. For example, the structural element 108 can be a rail configured for sliding the movable component within one or more slots (e.g., a server rail that slides in and out of a server rack). In other implementations, the structural element 108 can be a structural surface of the movable component. For example, a side surface of the movable component, a bottom surface of the movable component, or a top surface of the movable component (e.g., surfaces of a power circuit enclosure or an RF transceiver). When connected to the structural element 108, the condenser element 106 can interface with an enclosure of the electromechanical system. The interface provides both a thermal connection between the condenser element 106 and the enclosure and a structural connection between the movable component and the enclosure, via the structural element 108.

The thermal connection can be, for example, a low-thermal-resistance connection and can be a connection with the enclosure itself as described, or a connection with a heat sink associated with the electromechanical system, such as a cold plate connected to the enclosure (e.g., in a server cabinet or an avionics enclosure). The structural connection can be, for example, a substantially fixed mechanical connection between the movable component and the enclosure. The structural connection can be used to limit relative motion between the movable component and the enclosure and hold the relative positions of the movable component and the enclosure stable, to maintain the thermal connection.

For example, FIG. 1C illustrates example structural connections between the structural element 108 and a mating interface 110 of the enclosure. The examples are shown as a rail and rack system (e.g., for a server rack), but other configurations are possible. A detail view 100-6 shows an unconnected example, for clarity of the other views. The detail view 100-6 shows end views of the structural element 108 (coupled with the condenser element 106 and showing part of the flexible heat flow element 104) and the mating interface 110. Another detail view 100-7 depicts the structural element 108, again coupled with the condenser element 106 and the flexible heat flow element 104. In the detail view 100-7, the structural element 108 is inserted into the slots of the mating interface 110. The structural element 108 provides the structural connection to hold the movable component (e.g., the rail) securely in the enclosure. Further, because the flexible heat flow element 104 has been formed to fit the geometry of the enclosure (and/or is elastically flexible), the structural element 108 coupled with the condenser element 106 can also provide a thermal connection 112.

In some implementations, the mating interface 110 can include heat sink features, such as fluid channels 116 for a coolant to flow through. Additionally or alternatively, the mating interface 110 can include fins 118 that can reject heat into the surrounding environment. For clarity in the detail view 100-7, some fluid channels 116 and fins 118 are shown, but various different quantities, configurations, and/or shapes of the fluid channels 116 and/or the fins 118 can also be used.

Consider another detail view 100-8, which depicts the structural element 108, again coupled with the condenser element 106, but without the flexible heat flow element 104. In the detail view 100-8, the structural element 108 is inserted into the slots of the mating interface 110. Without the flexible heat flow element 104, the structural element 108 may not provide a secure structural connection or an efficient thermal connection. Instead, the structural element 108 coupled with the condenser element 106 may not fit well and create gaps 114, which can reduce the efficiency of the thermal connection. For example, a middle section that is not flexible may create a rotational force on the structural element 108 that pulls the structural element 108 away from the mating interface 110, creating the gaps 114.

Similarly, the evaporator unit (or units) 102 are coupled to the heat source (e.g., a processor, an RF transceiver, or a power-management component) to form a physical connection and a thermal connection with the heat source to transfer heat away from the heat source. While not shown in FIG. 1C, the flexible heat flow element 104 also enables a more efficient thermal connection (e.g., a low-thermal-resistance connection). As with the condenser element 106, without the flexible heat flow element 104, the evaporator 102 and the heat source may not provide an efficient thermal connection. Instead, the physical connection may be poor (e.g., create gaps similar to gaps 114), which can reduce the efficiency of the thermal connection.

Returning now to FIG. 1A: In some cases, the evaporator element 102 and/or the condenser element 106 can be made from rigid materials that can be bent, such as metals, foils, polymers. Fabrication methods can include traditional machining or additive metal manufacturing of the rigid parts (e.g., “3D printing”). The evaporator element 102 and/or the condenser element 106 may be made from a single (e.g., one) part with the channels cut through or as multiple (e.g., two, three, or more) parts with a channel etched or cut into one or both parts, which are then fused together. In some implementations, the channels can include a separate part (e.g., flexible metal or foil tubing) that is inserted in the channels. The evaporator element 102 and the condenser element 106 can then be attached to flexible heat flow element 104 at opposite ends. In other cases, the entire heat exchange device 100 can be fabricated as one piece in which the walls of the flexible heat flow element 104 are constructed to enable the flexible heat flow element 104 to be bent as needed to fit the shape of the electromechanical system enclosure and packaging.

The flexible heat flow element 104 is joined to the evaporator element 102 and the condenser element 106 (or to multiple instances of one or both). In some implementations, the joints between the flexible heat flow element 104 and the evaporator element 102 or the condenser element 106 can be formed as nonplanar angles (e.g., greater than or less than 180 degrees). The nonplanar angle between the flexible heat flow element 104 and the evaporator element 102 or the nonplanar angle between the flexible heat flow element 104 and the condenser element 106 can be different angles or the same angle.

In some cases, the joints between the flexible heat flow element 104 and the evaporator element 102 or the condenser element 106 can be made within the rigid material surrounding the channels. For example, the angle in the channel can be surrounded by the rigid material so that the channel angle is not exposed. This can help protect the joint and may enable better alignment of the joints between the flexible heat flow element 104 and the evaporator element 102 and/or the condenser element 106.

In some implementations, the evaporator element 102 and/or the condenser element 106 is bent to provide a clamping force to the contact with the heat source and/or the structural element 108. For example, either or both the evaporator element 102 or the condenser element 106 can be made as a clip (e.g., a U-shaped or C-shaped clip) in which the ends of the clip are closer together than the thickness of the target (e.g., the heat source or the structural element 108) so that there is a clamping force holding the clip in place. In other cases, the clip can include a spring to provide the clamping force.

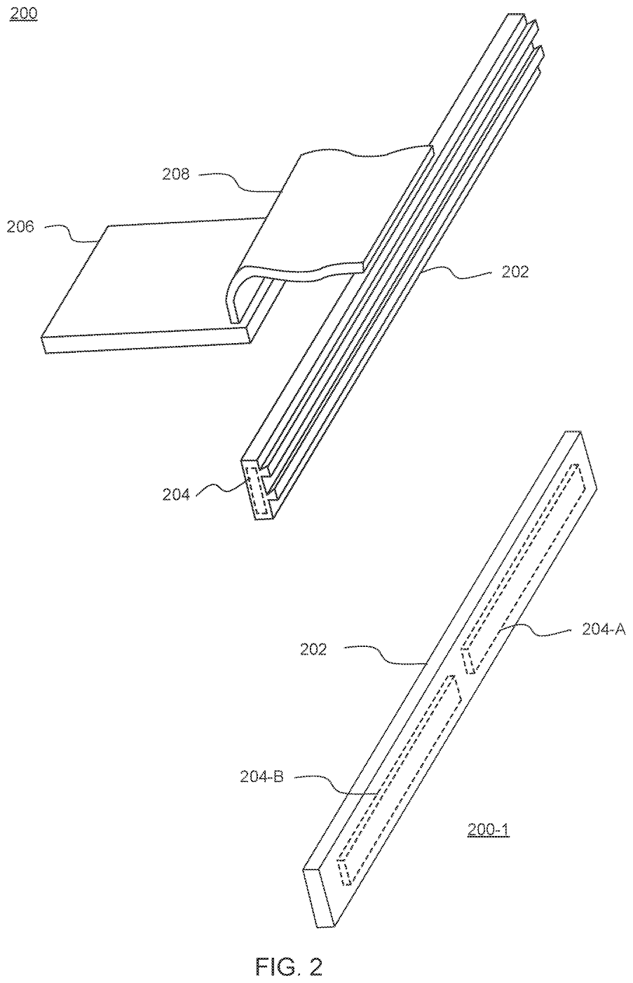

FIG. 2 illustrates an example structural component 200 for a mechanical connection to an electromechanical system that can be used to implement a flexible heat exchange device. The structural component 200 can include or be a part of a rigid body 202 that can connect to a movable component of the electromechanical system to provide a mechanical connection between the movable component and an enclosure of the electromechanical system. For example, the structural component 200 can be a rail configured for sliding the movable component within one or more slots (e.g., a server rail that slides in and out of a server rack). In other implementations, such as an avionics enclosure (not shown in FIG. 2), a part of the enclosure itself (e.g., a wall of the enclosure) can be removeable and serve as the structural component. In this case, another type of connection, such as a “face-to-face” contact connection, rather than a sliding connection, may be appropriate.

In other implementations, the structural component 200 can be a structural surface of the movable component (e.g., a side surface of the movable component, a bottom surface of the movable component, or a top surface of the movable component. The mechanical connection can be, for example, a substantially fixed mechanical connection between the movable component and the enclosure, which limits relative motion between the movable component and the enclosure and holds the relative positions of the movable component and the enclosure stable. The stable mechanical connection not only supports the structure, but can help maintain the thermal connection. In some implementations, the structural component 200 can be the structural element 108 as described with reference to FIGS. 1A-1C.

The structural component 200 can also include a condenser element 204 coupled with the rigid body 202. The condenser element 204 can be removably coupled with the rigid body 202 or integrated with the rigid body 202. The condenser element 204 can be coupled to an evaporator element 206 via a flexible heat flow element 208 to enable heat to flow from the evaporator element 206 to the condenser element 204 through the flexible heat flow element 208. In some implementations, the condenser element 204, the evaporator element 206, and the flexible heat flow element 208 correspond to, respectively, the condenser element 106, the evaporator element 102, and the flexible heat flow element 104 as described with reference to FIGS. 1A-1C. The flexible heat flow element 208 can be made from any of a variety of ductile, non-brittle, bendable materials (e.g., metals, polymers). In some cases, the heat flow element 208 is elastically bendable, in others, plastically bendable.

In some implementations, the rigid body 202 can include one or more additional condenser elements 204. A detail view 200-1 illustrates the rigid body 202 with two condenser elements 204-A and 204-B. In such an implementation, the flexible heat flow element 208 (not shown in the detail view 200-1) can be divided to connect multiple evaporator elements 206 (not shown in the detail view 200-1) to the condenser elements 204-A and 204-B. While not shown in FIG. 2, the condenser element 204, the evaporator element 206, and the flexible heat flow element 208 include channels for a working fluid, as described with reference to detail views 100-1, 100-2, and 100-3 of FIG. 1A.

The condenser element 204 can provide a thermal connection between the rigid body 202 and the enclosure. For example, the thermal connection can be a low-thermal-resistance connection and can be a connection with the enclosure itself as described, or a connection with a heat sink associated with the electromechanical system, such as a cold plate connected to the enclosure (e.g., in a server cabinet or an avionics enclosure).

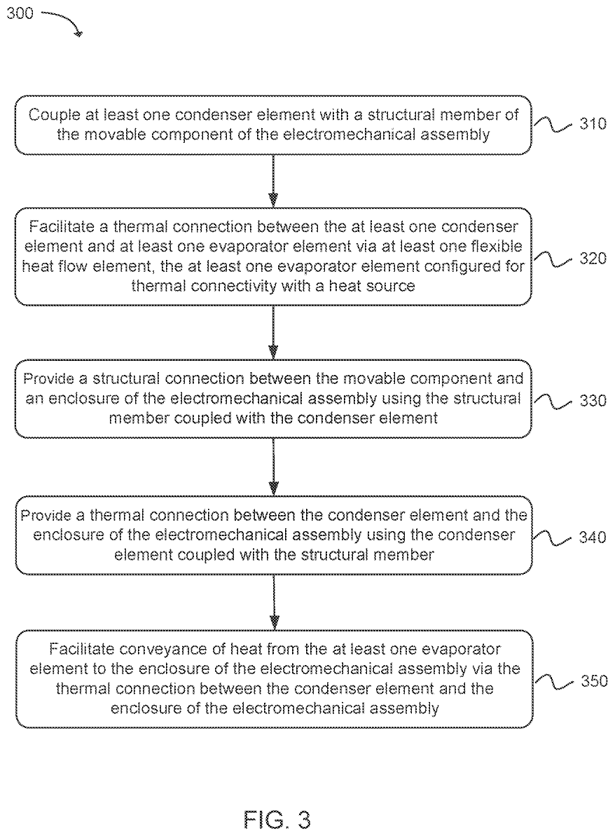

FIG. 3 is a flow diagram that illustrates an example method 300 for configuring an electromechanical assembly that includes at least one movable component. As in block 310, at least one condenser element can be coupled with a structural member of the movable component of the electromechanical assembly. The condenser element and the structural member can be removably coupled or permanently coupled (e.g., integrated). For example, the structural member can be a rail configured for sliding the movable component within one or more slots (e.g., a server rail that slides in and out of a server rack). In other implementations, the structural member can be a structural surface of the movable component, as described above.

As in block 320, a thermal connection between the at least one condenser element and at least one evaporator element can be facilitated via at least one flexible heat flow element. The at least one evaporator element can be configured for thermal connectivity with a heat source. The heat source can be associated with or included with the electromechanical assembly and can include, for example, a processor, an RF transceiver, or a power management component. The flexible heat flow element can be a flexible “′ribbon” that is coupled to the evaporator element to receive heat from the heat source, as described above.

A structural connection between the movable component and an enclosure of the electromechanical assembly can be provided using the structural member coupled with the condenser element, as in block 330. The structural connection can be, for example, a substantially fixed mechanical connection between the movable component and the enclosure, which can limit relative motion between the movable component and the enclosure and hold the relative positions of the movable component and the enclosure stable.

As in block 340, a thermal connection between the condenser element and the enclosure of the electromechanical assembly can be provided using the condenser element coupled with the structural member. The thermal connection can be, for example, a low-thermal-resistance connection with the heat source to transfer heat away from the heat source as described above. The thermal connection can be a connection with the enclosure itself as described, or a connection with a heat sink associated with the electromechanical system, such as a cold plate connected to the enclosure (e.g., in a server cabinet or an avionics enclosure). As noted, the structural connection can be used to limit relative motion between the movable component and the enclosure and hold the relative positions of the movable component and the enclosure stable, which can help to maintain the thermal connection.

Conveyance of heat from the at least one evaporator element to the enclosure of the electromechanical assembly can be facilitated via the thermal connection between the condenser element and the enclosure of the electromechanical assembly, as in block 350. For example, by coupling the condenser element and the structural member as described, heat from the heat source can be transferred away from the heat source to the enclosure and/or heat sink, as described above with reference to FIG. 1A through FIG. 2.

The present technology provides several significant advantages over prior related technology, some of which are recited here and throughout the following more detailed description. The present technology provides as one advantage that a combination of a flexible heat flow element between the evaporator and the condenser along with a mechanical connection can enable significantly improved thermal interfaces. For example, proper alignment (e.g., of the rail and the rack), enabled by flexibility of the heat flow element can facilitate an improved thermal connection between the condenser and the enclosure.

The present technology provides as another advantage that a non-planar angle between one or both of the flexible heat flow element and the evaporator element or between the flexible heat flow element and the condenser element can help (e.g., in addition to the flexibility) enable the customizable form factors that enable the improved thermal connection described above. Further, joining at an angle can enable better alignment of the fluid channels during the joining process.

The present technology provides as another advantage the option of including multiple condensers and/or evaporators. Multiple condensers can enable electromechanical assemblies to include components with higher heat flux loads, because effectively, each condenser needs to support only half of the heat load. Multiple evaporators can allow the heat exchange device to cool multiple heat sources associated with the electronics enclosure, while being supported by a single condenser side rail. Overall, this can lead to higher power density enclosures.

Each of the advantages recited herein will be apparent in light of the detailed description set forth herein, and with reference to the accompanying drawings. These advantages are not meant to be limiting in any way. Indeed, one skilled in the art will appreciate that other advantages may be realized, other than those specifically recited herein, upon practicing the present technology.

Moreover, the present technology provides various solutions to the problems inherent in the prior related technology as discussed herein. For example, because described technology is a passive, closed loop system, no fans or pumps are necessary, which can save cost and space, resulting in higher component density. Further, without fans or pumps, there may be fewer failure modes, which can improve the reliability of the cooling system. For example, no power is needed for running the fans or pumps and there are fewer liquid-filled joints (or none), which reduces the possibility of leaks. Moreover, because of the combined mechanical and thermal connection, the heat transfer between the condenser and the enclosure (or heat sink) can be improved in comparison with current techniques.

The following examples are further illustrative of several embodiments of the present technology:

In one example, the present disclosure sets forth a heat exchange device for an electromechanical system. The heat exchange device can comprise an evaporator element configured to be coupled to a heat source associated with the electromechanical system, a flexible heat flow element coupled to the evaporator element and configured to receive heat from the heat source via the evaporator element, and a condenser element connected to the flexible heat flow element. The condenser element can be coupled to a structural element of a movable component of the electromechanical system. The condenser element can also be configured to receive heat from the evaporator element via the flexible heat flow element. The condenser element can also be configured to interface with an enclosure of the electromechanical system to provide a thermal connection between the condenser element and the enclosure and also provide a structural connection between the movable component and the enclosure, via the structural element.

In an example, the flexible heat flow element can comprise a heat flow element that is ductile and elastically bendable or plastically bendable.

In some examples, the structural element of the movable component of the electromechanical system can comprise a rigid body. The rigid body can further comprise at least one of: a rail configured for sliding the movable component within one or more slots of the enclosure, a side surface of the movable component, a bottom surface of the movable component, or a top surface of the movable component.

In some examples, the structural connection can comprise a substantially fixed mechanical connection between the movable component and the enclosure.

The heat exchange device can further comprise one or more of: at least one additional evaporator element and at least one additional condenser element.

In an example, the enclosure for the electromechanical system can include, or be in thermal communication with, a heat sink.

In some examples, the heat exchange device can comprise an oscillating heat pipe.

The heat exchange device can also comprise at least one of: a first joint between the flexible heat flow element and the evaporator element, the first joint forming a first nonplanar angle between the flexible heat flow element and the evaporator element; or a second joint between the flexible heat flow element and the condenser element, the second joint forming a second nonplanar angle between the flexible heat flow element and the condenser element.

In one example, the present disclosure also sets forth a structural component for a mechanical connection to an electromechanical system. The structural component can comprise a rigid body configured to connect to a movable component of the electromechanical system and provide the mechanical connection between the movable component and an enclosure of the electromechanical system. The structural component can also comprise a condenser element. The condenser element can be coupled with the rigid body and configured to couple to an evaporator element via a flexible heat flow element to enable heat to flow from the evaporator element to the condenser element through the flexible heat flow element. The condenser element can also be configured to provide a thermal connection between the rigid body and the enclosure.

In an example, the rigid body can further comprise a rail configured for sliding the movable component within one or more slots of the enclosure.

In some examples, the rigid body can further comprise at least one of a side surface of the movable component, a bottom surface of the movable component, or a top surface of the movable component.

In an example, the flexible heat flow element comprises a heat flow element that is ductile and: elastically bendable; or plastically bendable.

In some examples, the mechanical connection comprises a substantially fixed mechanical connection between the movable component and the enclosure.

The structural component can also comprise at least one additional condenser element.

In an example, the enclosure of the electromechanical system can include, or be in thermal communication with, a heat sink.

In one example, the present disclosure also sets forth a method for configuring an electromechanical assembly that includes at least one movable component. The method can comprise coupling at least one condenser element with a structural member of the movable component of the electromechanical assembly. The method can also comprise facilitating a thermal connection between the at least one condenser element and at least one evaporator element via at least one flexible heat flow element. The at least one evaporator element can be configured for thermal connectivity with a heat source. The method can further comprise providing a structural connection between the movable component and an enclosure of the electromechanical assembly using the structural member coupled with the condenser element. The method can also comprise providing a thermal connection between the condenser element and the enclosure of the electromechanical assembly using the condenser element coupled with the structural member. The method can further comprise facilitating conveyance of heat from the at least one evaporator element to the enclosure of the electromechanical assembly via the thermal connection between the condenser element and the enclosure of the electromechanical assembly.

In some examples, providing the structural connection can comprise providing a substantially fixed mechanical connection between the movable component and the enclosure.

In some examples, the method can further comprise providing a heat sink that is coupled to, or in thermal communication with, the enclosure for the electromechanical assembly.

Reference was made to the examples illustrated in the drawings and specific language was used herein to describe the same. It will nevertheless be understood that no limitation of the scope of the technology is thereby intended. Alterations and further modifications of the features illustrated herein and additional applications of the examples as illustrated herein are to be considered within the scope of the description.

Although the disclosure may not expressly disclose that some embodiments or features or examples described herein may be combined with other embodiments or features or examples described herein, this disclosure should be read to describe any such combinations that would be practicable by one of ordinary skill in the art. Indeed, the above detailed description of embodiments of the present technology are not intended to be exhaustive or to limit the present technology to the precise form disclosed above. Although specific embodiments of, and examples for, the present technology are described above for illustrative purposes, various equivalent modifications are possible within the scope of the present technology as those skilled in the relevant art will recognize. For example, although steps (e.g., of a method) are presented in a given order, alternative embodiments can perform steps in a different order. The various embodiments described herein can also be combined to provide further embodiments.

Furthermore, the described features, structures, characteristics or examples of the present technology may be combined in any suitable manner in one or more examples. In the preceding description, numerous specific details were provided, such as examples of various configurations to provide a thorough understanding of examples of the described technology. It will be recognized, however, that the present technology may be practiced without one or more of the specific details, or with other methods, components, devices, etc. In other instances, well-known structures or operations are not shown or described in detail to avoid obscuring aspects of the technology.

Moreover, unless the word “or” is expressly limited to mean only a single item exclusive from other items in reference to a list of two or more items, then the use of “or” in such a list is to be interpreted as including (a) any single item in the list, (b) all of the items in the list, or (c) any combination of the items in the list. In other words, the use of “or” in this disclosure should be understood to mean non-exclusive “or” (i.e., “and/or”) unless otherwise indicated herein.

Additionally, the term “comprising” is used throughout to mean including at least the recited feature(s) such that any greater number of the same feature and/or additional types of other features are not precluded. It will also be appreciated that specific embodiments have been described herein for purposes of illustration, but that various modifications can be made without deviating from the technology. Further, while advantages associated with some embodiments of the present technology have been described in the context of those embodiments, other embodiments can also exhibit such advantages, and not all embodiments need necessarily exhibit such advantages to fall within the scope of the technology. Accordingly, the disclosure and associated present technology can encompass other embodiments not expressly shown or described herein.

Although the subject matter has been described in language specific to structural features and/or operations, it is to be understood that the subject matter defined in the appended claims is not necessarily limited to the specific features and operations described above. Rather, the specific features and acts described above are disclosed as example forms of implementing the claims. Numerous modifications and alternative arrangements may be devised without departing from the spirit and scope of the described present technology.

What is claimed is:

1. A heat exchange device for an electromechanical system, comprising:
an evaporator element configured to be coupled to a heat source associated with the electromechanical system;
a flexible heat flow element coupled to the evaporator element and configured to receive heat from the heat source via the evaporator element; and
a condenser element connected to the flexible heat flow element, the condenser element:
coupled to a structural element of a movable component of the electromechanical system; and
configured to:
receive heat from the evaporator element via the flexible heat flow element; and
interface with an enclosure of the electromechanical system to provide:
a thermal connection between the condenser element and the enclosure; and
a structural connection between the movable component and the enclosure, via the structural element.

2. The heat exchange device of claim 1, wherein the flexible heat flow element comprises a heat flow element that is ductile and:
elastically bendable; or
plastically bendable.

3. The heat exchange device of claim 1, wherein the structural element of the movable component of the electromechanical system comprises a rigid body.

4. The heat exchange device of claim 3, wherein the rigid body further comprises at least one of:
a rail configured for sliding the movable component within one or more slots of the enclosure;
a side surface of the movable component;
a bottom surface of the movable component; or
a top surface of the movable component.

5. The heat exchange device of claim 1, wherein the structural connection comprises a substantially fixed mechanical connection between the movable component and the enclosure.

6. The heat exchange device of claim 1, further comprising at least one additional evaporator element.

7. The heat exchange device of claim 1, further comprising at least one additional condenser element.

8. The heat exchange device of claim 1, wherein the enclosure for the electromechanical system includes, or is in thermal communication with, a heat sink.

9. The heat exchange device of claim 1, wherein the heat exchange device comprises an oscillating heat pipe.

10. The heat exchange device of claim 1, further comprising at least one of:
a first joint between the flexible heat flow element and the evaporator element, the first joint forming a first nonplanar angle between the flexible heat flow element and the evaporator element; or
a second joint between the flexible heat flow element and the condenser element, the second joint forming a second nonplanar angle between the flexible heat flow element and the condenser element.

11. A structural component for a mechanical connection to an electromechanical system, the structural component comprising:
a rigid body configured to:
connect to a movable component of the electromechanical system; and
provide the mechanical connection between the movable component and an enclosure of the electromechanical system; and
a condenser element, the condenser element coupled with the rigid body and configured to:
couple to an evaporator element via a flexible heat flow element to enable heat to flow from the evaporator element to the condenser element through the flexible heat flow element; and
provide a thermal connection between the rigid body and the enclosure.

12. The structural component of claim 11, wherein the rigid body further comprises:
a rail configured for sliding the movable component within one or more slots of the enclosure.

13. The structural component of claim 11, wherein the rigid body further comprises at least one of:
a side surface of the movable component;
a bottom surface of the movable component; or
a top surface of the movable component.

14. The structural component of claim 11, wherein the flexible heat flow element comprises a heat flow element that is ductile and:
elastically bendable; or
plastically bendable.

15. The structural component of claim 11, wherein the mechanical connection comprises a substantially fixed mechanical connection between the movable component and the enclosure.

16. The structural component of claim 11, further comprising at least one additional condenser element.

17. The structural component of claim 11, wherein the enclosure of the electromechanical system includes, or is in thermal communication with, a heat sink.

18. A method for configuring an electromechanical assembly that includes at least one movable component, the method comprising:
coupling at least one condenser element with a structural member of the movable component of the electromechanical assembly;
facilitating a thermal connection between the at least one condenser element and at least one evaporator element via at least one flexible heat flow element, the at least one evaporator element configured for thermal connectivity with a heat source;
providing a structural connection between the movable component and an enclosure of the electromechanical assembly using the structural member coupled with the condenser element;
providing a thermal connection between the condenser element and the enclosure of the electromechanical assembly using the condenser element coupled with the structural member; and
facilitating conveyance of heat from the at least one evaporator element to the enclosure of the electromechanical assembly via the thermal connection between the condenser element and the enclosure of the electromechanical assembly.

19. The method of claim 18, wherein providing the structural connection comprises providing a substantially fixed mechanical connection between the movable component and the enclosure.

20. The method of claim 18, further comprising:
providing a heat sink that is coupled to, or in thermal communication with, the enclosure for the electromechanical assembly.
